(19) United States
(12) Patent Application Publication
(10) Pub. No.: US 2019/0164902 A1
(43) Pub. Date: May 30, 2019

(54) PACKAGE ASSEMBLY FOR DIVIDED ELECTROMAGNETIC SHIELDING AND METHOD OF MANUFACTURING SAME

(71) Applicant: SHUNSIN TECHNOLOGY (ZHONG SHAN) LIMITED, Zhongshan (CN)

(72) Inventor: JUN-YI XIAO, Shenzhen (CN)

(21) Appl. No.: 15/860,679

(22) Filed: Jan. 3, 2018

(30) Foreign Application Priority Data
Nov. 24, 2017 (CN) 201711194388.3

(51) Int. Cl. H01L 23/552; H01L 25/00; H01L 25/065; H01L 21/56; H01L 23/498; H01L 21/48

(52) U.S. Cl. CPC H01L 23/552; H01L 25/50; H01L 25/0655; H01L 23/49827; H01L 23/49838; H01L 21/4803; H01L 21/561

(57) ABSTRACT

A package assembly for divided electromagnetic shielding includes a substrate, pad groups, chips, a first colloid, an electromagnetic shielding layer, and a second colloid. The pad groups on the substrate are separate and electrically connected to the substrate. Chips are soldered on the pad groups, and each chip corresponds to one pad group. The first colloid covers the chips as a seal, the electromagnetic shielding layer being electroplated onto the outer layer of the first colloid. The second colloid is injected on an outer layer of the electromagnetic shielding layer to cover the electromagnetic shielding layer and form a package assembly. The package assembly can be cut into separate products. A method of manufacturing the package assembly is also provided.

### FIELD

The subject matter herein generally relates to package assemblies for chips and methods of manufacturing the package assemblies, and more particularly to a package assembly for divided electromagnetic shielding, and a method of manufacturing such package assembly.

### BACKGROUND

In existing technology, manufacture a package assembly for divided electromagnetic shielding is mainly divided into the following two methods:

One is to semi cut the package assembly and then process the electromagnetic shielding;

The other one is to semi cut the packaging assembly, then dispensing, and finally process electromagnetic shielding.

In view of the above schemes, the semi cutting operation increases the manufacturing cycle and cost, and the substrate is prone to warp during the semi cutting process, which result in lower product yield and poor appearance. In addition, gas holes often appear in the dispensing process, which result in wayward product yield, and the cost of silver glue is high.

### BRIEF DESCRIPTION OF THE DRAWINGS

Implementations of the present technology will now be described, by way of example only, with reference to the attached figures, wherein:

FIG. 1 is a cross-sectional view of a package assembly for divided electromagnetic shielding, according to a first exemplary embodiment of the disclosure.

FIG. 2 is a flow chart of an exemplary method of manufacturing the package assembly of FIG. 1.

FIG. 3 is a cross-sectional view of manufacturing substrate outer line, according to the method of FIG. 2, of the package assembly of FIG. 2.

FIG. 4 is a cross-sectional view of forming pad group on the substrate of FIG. 3, according to the method of FIG. 2.

FIG. 5 is a cross-sectional view of soldering chip on the substrate of FIG. 3, according to the method of FIG. 2.

FIG. 6 is a cross-sectional view of injecting a first colloid to the package assembly of FIG. 2, according to the method of FIG. 2.

FIG. 7 is a cross-sectional view of electroplating metal on exterior surface of the first colloid, according to the method of FIG. 2.

FIG. 8 is a cross-sectional view of injecting a second colloid of the package assembly of FIG. 2, according to the method of FIG. 2.

FIG. 9 is a cross-sectional view of cutting the package assembly of FIG. 2 into separated products, according to the method of FIG. 2.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “outside” refers to a region that is beyond the outermost confines of a physical object. The term “inside” indicates that at least a portion of a region is partially contained within a boundary formed by the object. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is described in relation to a package assembly for a divided electromagnetic shielding.

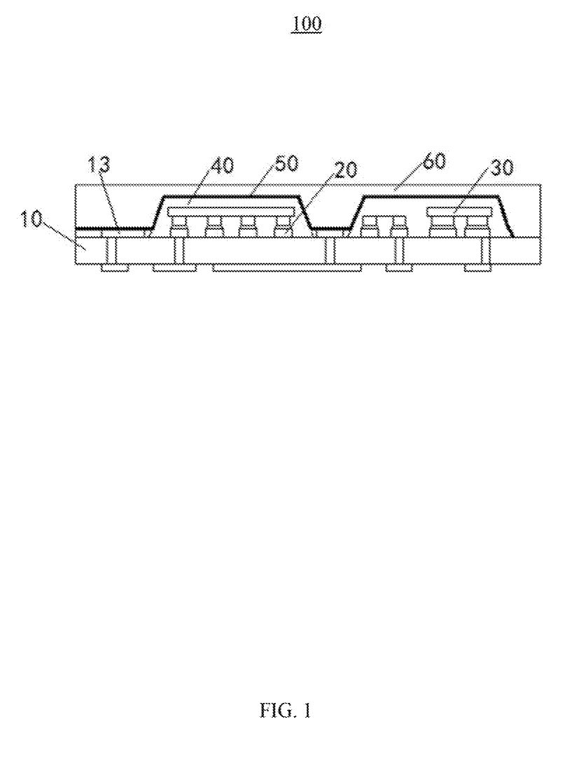

FIG. 1 illustrates a package assembly for divided electromagnetic shielding 100, according to a first exemplary embodiment of the disclosure. The package assembly 100 includes a substrate 10. The package assembly 100 further includes a plurality of pad groups 20, a plurality of chips 30, a first colloid 40, an electromagnetic shielding layer 50, and a second colloid 60 located on the substrate 10. As shown in FIG. 1, the substrate 10 includes a top surface 11 and a bottom surface 12 opposite to the top surface 11. A plurality of grounding lines 13 is formed on the top surface 11 of the substrate 10, a plurality of grounding layers 14 is formed on the bottom surface 12, and the grounding line 13 is electrically connected to the grounding layer 14. The pad group 20 is located on the top surface 11 of the substrate 10 between two or more adjacent grounding lines 13, and the grounding lines 13 are spaced apart from the pad groups 20. Each pad group 20 corresponds to a chip 30, multiple chips 30 being spaced, and each chip 30 is individually covered by the first colloid 40. That is, a plurality of chips 30 is mounted on the substrate 10, and each chip 30 is independent from others. A metal material is electroplated onto the outer layer of the first colloid 40 and the grounding lines 13 to form the electromagnetic shielding layer 50. The electromagnetic shielding layer 50 is connected to the grounding lines 13 and thus provides electromagnetic shielding. The second colloid 60 is injected on an outer layer of the electromagnetic shielding layer 50 and covers the metal material to form a package assembly. According to requirements, the package assembly can be cut into separate products.

In the embodiment, SIP (System in a Package) as an assembly technique. With the popularity of smart phones and internet, the expected complexity of the SIP module is increasing, and the potential for divided electromagnetic shielding is large.

In each of the package assemblies for divided electromagnetic shielding 100, the plurality of chips 30 is separated by the first colloid 40, and then the electromagnetic shielding layer 50 is electroplated on the first colloid 40, and the electromagnetic shielding layer 50 is inside the package body. Metal material does not need to be electroplated on the outer surface of package assembly 100, warping caused by the semi cutting of the packaged product is avoided, and the package assembly for divided electromagnetic shielding 100 can effectively improve the yield of the product and improve the appearance of the product.

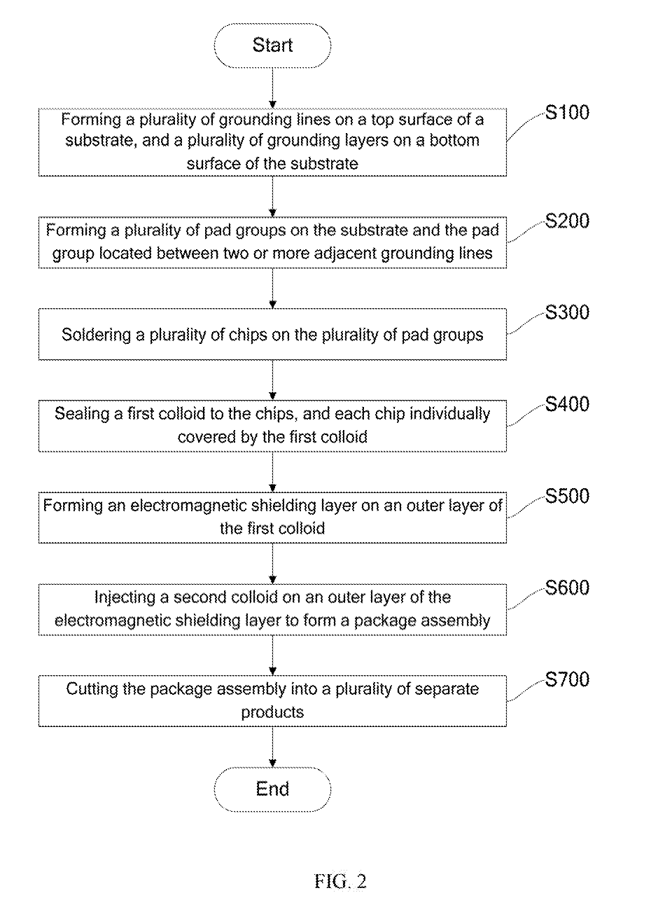

Referring to FIG. 2, an exemplary method of manufacturing the package assembly 100, to package a chip 30 on a substrate 10 with divided electromagnetic shielding, is illustrated. The method of manufacturing the package assembly 100 comprises the following steps.

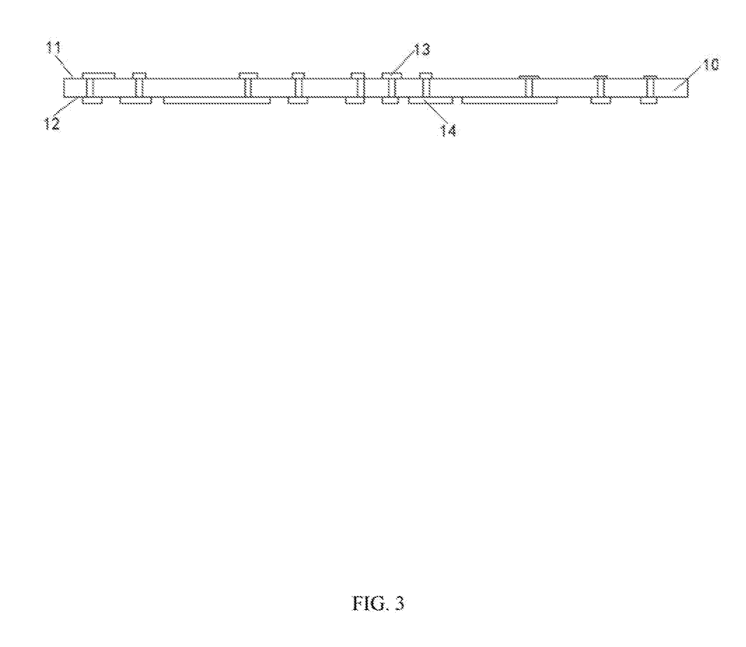

FIGS. 2 and 3 illustrate that in step 100, a top surface 11 of the substrate 10 has a plurality of grounding lines 13, a bottom surface 12 has a plurality of grounding layers 14, and the grounding line 13 is electrically connected to the grounding layer 14.

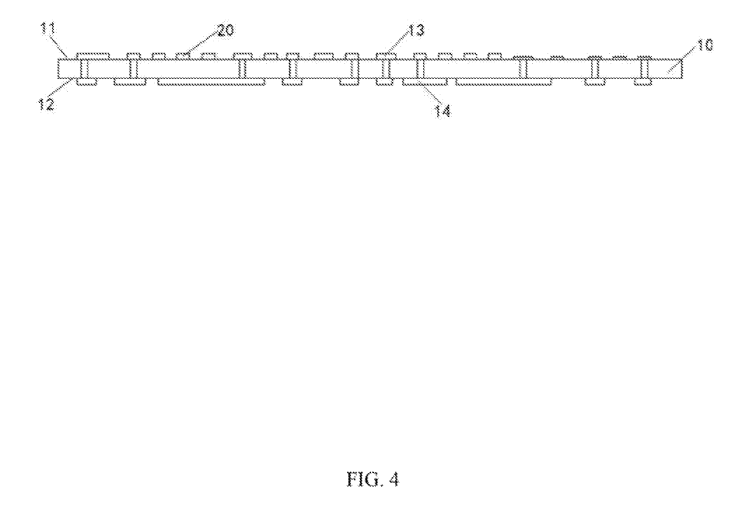

FIGS. 2 and 4 illustrate that in step 200, a plurality of pad groups 20 is located on the top surface 11 of the substrate 10 between two or more adjacent grounding lines 13.

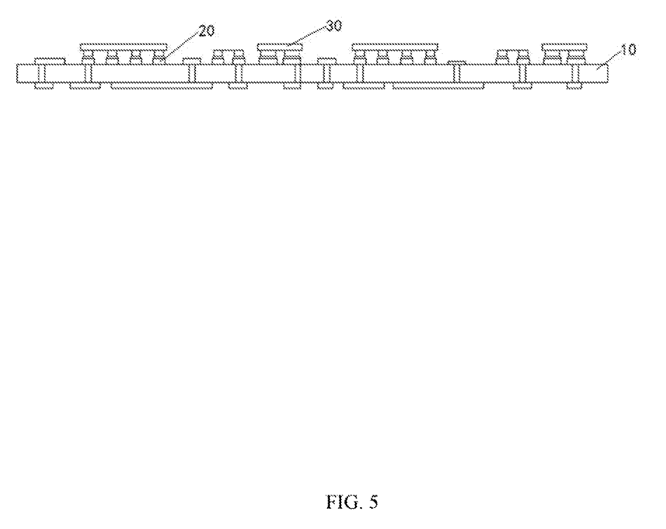

FIGS. 2 and 5 illustrate that in step 300, a chip 30 is soldered on the pad group 20, and each pad group 20 corresponds to one chip 30.

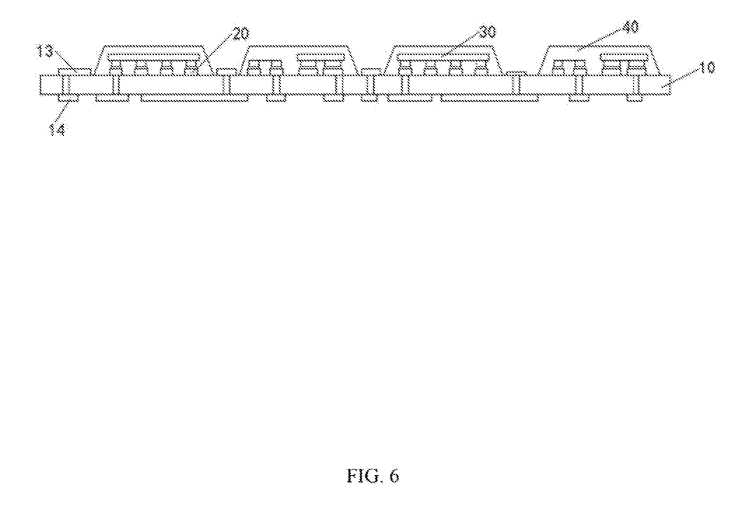

FIGS. 2 and 6 illustrate that in step 400, multiple chips 30 are spaced apart and each chip 30 is individually covered by a first colloid 40. That is, a plurality of chips 30 is mounted on the substrate 10, and each chip 30 is independent.

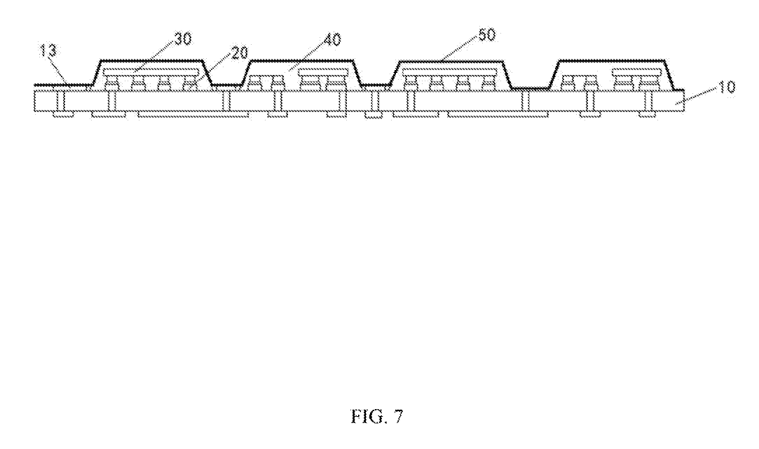

FIGS. 2 and 7 illustrate that in step 500, a metal material is electroplated onto an outer layer of the first colloid 40 and the grounding lines 13 to form an electromagnetic shielding layer 50. Since the electromagnetic shielding layer 50 is connected to the grounding lines 13, electromagnetic shielding is thus created.

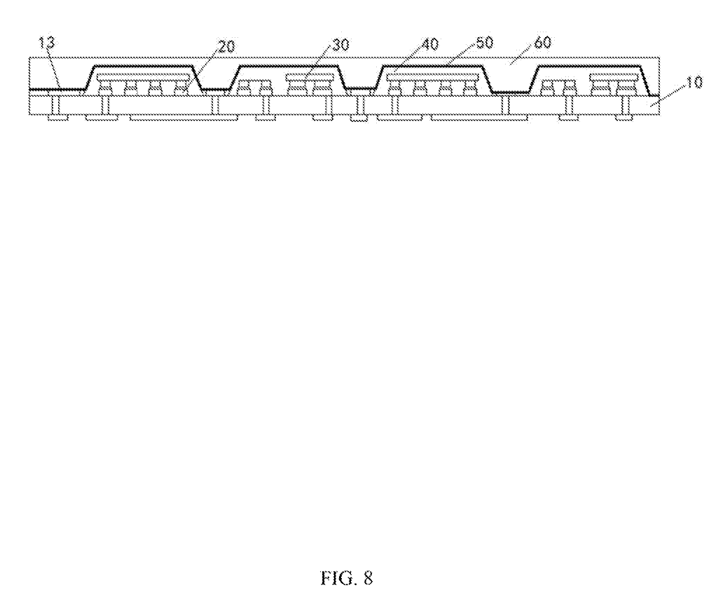

FIGS. 2 and 8 illustrate that in step 600, a second colloid 60 is injected on an outer layer of the electromagnetic shielding layer 50 and covers the metal material to form a package assembly.

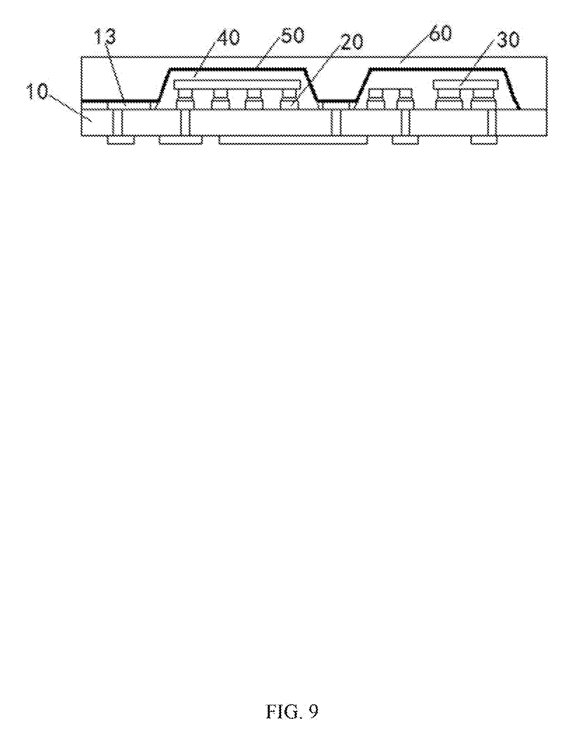

FIGS. 2 and 9 illustrate that in step 700, according to requirements, the package assembly can be cut into a plurality of separate products.

SIP (System in a Package) is used as an assembly technique. With the popularity of smart phones and internet, the expected complexity of the SIP module is increasing, and the potential for divided electromagnetic shielding is large.

In summary, taking the package assembly 100 and the above-described manufacturing method as examples, each of the plurality of chips 30 is separated by the first colloid 40, and then the electromagnetic shielding layer 50 is electroplated on the first colloid 40, the electromagnetic shielding layer 50 being thus inside the package body. Metal material does not need to be electroplated on the outer surface of package assembly 100, warping by the semi cutting of the packaged product is avoided, and the package assembly for divided electromagnetic shielding 100 can effectively improve the yield of the product and improve the appearance of the product.

The embodiments shown and described above are only examples. Many details are often found in the art such as the other features of a package assembly for divided electromagnetic shielding and method of manufacturing same. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

1. A package assembly for divided electromagnetic shielding, the package assembly comprising:
a substrate comprising a top surface forming a plurality of grounding lines;
a plurality of pad groups on the substrate and electrically connected to the substrate;
a plurality of chips soldered on the pad groups;
a first colloid covered on the chips to seal each chip independent from others;
an electromagnetic shielding layer electroplated onto an outer layer of the first colloid;
a second colloid injected on an outer layer of the electromagnetic shielding layer to cover the electromagnetic shielding layer and form a package assembly, wherein the grounding lines, the electromagnetic shielding layer, and the top surface of the substrate cooperatively form a closed space, and one of the chip is in the closed space.

2. The package assembly of claim 1, wherein the substrate includes a bottom surface opposite to the top surface, the bottom surface is formed a plurality of grounding layers, and the grounding line is electrically connected to the grounding layer.

3. The package assembly of claim 2, wherein the pad group is located on the top surface of the substrate and between two or more adjacent grounding lines.

4. The package assembly of claim 3, wherein the electromagnetic shielding layer is covered on the grounding lines and connected to the grounding lines.

5. A package assembly manufacturing method, comprising:
forming a plurality of pad groups on a substrate;
soldering a plurality of chips on the plurality of pad groups, and each chip corresponding to a pad group;
sealing a first colloid to the chips, and each chip individually covered by the first colloid;
forming an electromagnetic shielding layer on an outer layer of the first colloid;
injecting a second colloid on an outer layer of the electromagnetic shielding layer to form a package assembly;
cutting the package assembly into a plurality of separated products.

6. The method of claim 5, wherein further comprises:
forming a plurality of grounding lines on a top surface of the substrate;
forming a plurality of grounding layers on a bottom surface of the substrate, and the grounding line is electrically connected to the grounding layer.

7. The method of claim 6, wherein the pad group is located on the top surface of the substrate and between two or more adjacent grounding lines.

8. The method of claim 7, wherein the electromagnetic shielding layer is covered on the grounding lines and connected to the grounding lines.

9. The package assembly of claim 1, wherein an outer layer of the second colloid comprises no metal material.

10. The package assembly of claim 1, wherein one of the grounding lines is positioned between two of the plurality of chips and is not covered by the first colloid.

11. The package assembly of claim 1, wherein the first colloid respectively covering the plurality of chips is separated by one of the grounding lines.
